(19) United States
(12) Patent Application Publication
(10) Pub. No.: US 2025/0203756 A1
(43) Pub. Date: Jun. 19, 2025

(54) CIRCUIT BOARD MODULE CAPABLE OF SUPPRESSING COMMON MODE NOISE

(71) Applicant: EMPass Technology Inc., New Taipei City (TW)

(72) Inventors: Yang-Chih HUANG, New Taipei City (TW); Chin-Yi LIN, New Taipei City (TW)

(21) Appl. No.: 18/977,684

(22) Filed: Dec. 11, 2024

(30) Foreign Application Priority Data
Dec. 13, 2023 (TW) 112148444

(51) Int. Cl. H05K 1/02

(52) U.S. Cl. CPC H05K 1/0216; H05K 1/0215; H05K 2201/09227; H05K 2201/09272

(57) ABSTRACT

A circuit board module capable of suppressing common mode noise includes a circuit board, and a first circuit and a second circuit that are disposed on the circuit board. The circuit board includes an insulating substrate, and a plurality of metal layers. The metal layers are disposed in the insulating substrate, are spaced apart from each other, and include a first metal layer and a second metal layer. The metal layers are formed to include a plurality of conducting lines. The conducting lines cooperatively form a common mode choke structure in which the conducting lines extend in a spiral pattern, so that each of the conducting lines has a spiral winding segment in the spiral pattern. In the spiral pattern, a mutual inductance coupling coefficient between the spiral winding segments of two adjacent ones of the conducting lines is greater than 0.3.

### CROSS-REFERENCE TO RELATED APPLICATION

This application claims priority to Taiwanese Invention patent Application No. 112148444, filed on Dec. 13, 2023, the entire disclosure of which is incorporated by reference herein.

### FIELD

The disclosure relates to a circuit board module, and more particularly to a circuit board module capable of suppressing common mode noise.

### BACKGROUND

A conventional common mode choke (also known as common mode inductor) includes two conducting lines (coils) symmetrically wound in the same direction and with the same number of turns on a closed magnetic core. An equivalent circuit of the conventional common mode choke is shown in FIG. 1, where “L” represents an inductance of each of the two conducting lines, “M” represents a mutual inductance generated between the two conducting lines, and “C” represents a parasitic capacitance (C) of each of the two conducting lines. The inductances and the parasitic capacitances cooperatively form two parallel LC resonant cavities. When a common mode noise current flows through the conventional common mode choke (i.e., input at in+ and in−, and output at out+ and out−), in a common mode state, the two parallel LC resonant cavities will generate open-circuit resonances, thereby suppressing the common mode noise current.

Furthermore, by using materials with high magnetic permeability such as ferromagnetic materials in the magnetic core, the mutual inductance between the two conducting lines may be enhanced, which allows for a low insertion loss for a differential mode signal, ensuring minimal impact on a transmission of the differential mode signal, while achieving a high insertion loss for a common mode noise signal to suppress the common mode noise signal during a common mode noise signal transmission. However, a permeability of the magnetic core is related to a frequency of a transmission signal. When transmitting high-frequency signals, the permeability of the magnetic core decreases, causing the mutual inductance between the two conducting lines to decrease. As a result, the insertion loss of the differential mode signal increases and the ability to suppress the common mode noise signal decreases.

Additionally, the conventional common mode choke utilizes inductors with enhanced inductance via ferromagnetic materials, and the parasitic capacitance to determine a common mode transmission zero (i.e., a resonant frequency of the common mode noise signal) of the conventional common mode choke. This resonant frequency is inversely related to the values of the inductance and the parasitic capacitance. Therefore, in order to shift the common mode transmission zero to a lower frequency, the inductance value needs to be increased, which requires the length of the two conducting lines (coils) to be increased. However, increasing the length of the two conducting lines increases the layout of the conventional common mode choke and its size, and raises line losses.

### SUMMARY

Therefore, an object of the disclosure is to provide a circuit board module capable of suppressing common mode noise that can alleviate at least one of the drawbacks of the prior art.

According to the disclosure, the circuit board module includes a circuit board, a first circuit and a second circuit. The circuit board includes an insulating substrate and a plurality of metal layers. The metal layers are disposed in the insulating substrate and are spaced apart from each other. The metal layers include a first metal layer that has a plurality of first connecting nodes, and a second metal layer that has a plurality of second connecting nodes. The first circuit is disposed on the circuit board and is electrically connected to the first connecting nodes. The second circuit is disposed on the circuit board and is electrically connected to the second connecting nodes.

The metal layers are formed to include a plurality of conducting lines, each having an end connected to a respective one of the first connecting nodes, and another end connected to a respective one of the second connecting nodes. The conducting lines cooperatively form a common mode choke structure in which the conducting lines extend in such a way that each of the conducting lines has a spiral winding segment, and that projections respectively of the spiral winding segments of the conducting lines onto a same plane that is parallel to the metal layers extend side by side in a spiral pattern. In the spiral pattern, a mutual inductance coupling coefficient between the spiral winding segments of two adjacent ones of the conducting lines is greater than 0.3.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a circuit diagram illustrating an equivalent circuit of a conventional common mode choke.

FIG. 2 is a perspective view illustrating a circuit board module according to a first embodiment of the present disclosure.

FIG. 3 is a perspective view illustrating a first circuit and a second circuit disposed on a circuit board according to the first embodiment of the present disclosure.

FIG. 4 is a top view illustrating a common mode choke structure of the circuit board according to the first embodiment of the present disclosure.

FIG. 5 is a circuit diagram illustrating an equivalent circuit of the common mode choke structure according to the first embodiment of the present disclosure.

FIG. 5A is a circuit diagram illustrating another equivalent circuit of the common mode choke structure according to the first embodiment of the present disclosure.

FIGS. 6 and 7 are respectively a perspective diagram and a top view illustrating the common mode choke structure of the circuit board according to a second embodiment of the present disclosure.

FIGS. 8 and 9 are respectively a perspective diagram and a top view illustrating the common mode choke structure of the circuit board according to a third embodiment of the present disclosure.

FIGS. 10 and 11 are respectively a perspective diagram and a top view illustrating the common mode choke structure of the circuit board according to a fourth embodiment of the present disclosure.

FIGS. 12 and 13 are respectively a perspective diagram and a top view illustrating the common mode choke structure of the circuit board according to a fifth embodiment of the present disclosure.

FIGS. 14 and 15 are respectively a perspective diagram and a top view illustrating a variation of the common mode choke structure of the fifth embodiment.

FIG. 16 is an S21 plot illustrating insertion loss and common mode suppression characteristics of the fifth embodiment and the first embodiment that has the common mode choke structure with the equivalent circuit the same as in FIG. 5.

FIGS. 17 and 18 are respectively a perspective diagram and a top view illustrating the common mode choke structure of the circuit board according to a sixth embodiment of the present disclosure.

FIG. 19 is an S21 plot illustrating insertion loss and common mode suppression characteristics of the sixth embodiment and the first embodiment that has the common mode choke structure with the equivalent circuit the same as in FIG. 5.

FIGS. 20 and 21 are respectively a perspective diagram and a top view illustrating the common mode choke structure of the circuit board according to a seventh embodiment of the present disclosure.

FIG. 22 is an S21 plot illustrating insertion loss and common mode suppression characteristics of the seventh embodiment and the first embodiment that has the common mode choke structure with the equivalent circuit the same as in FIG. 5.

FIGS. 23 and 24 are respectively a perspective diagram and a top view illustrating a variation of a spiral pattern of the first embodiment.

FIGS. 25 and 26 are respectively a perspective diagram and a top view illustrating another variation of the spiral pattern of the first embodiment.

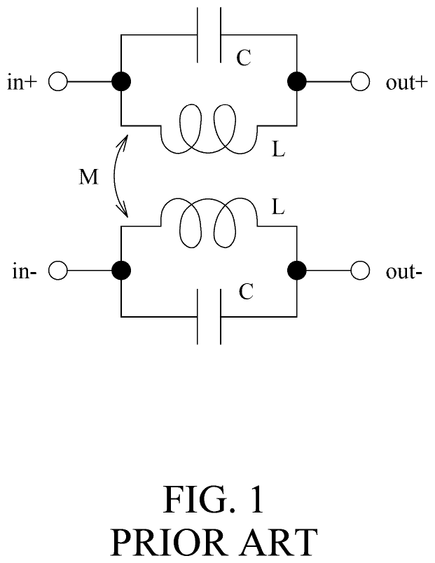

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

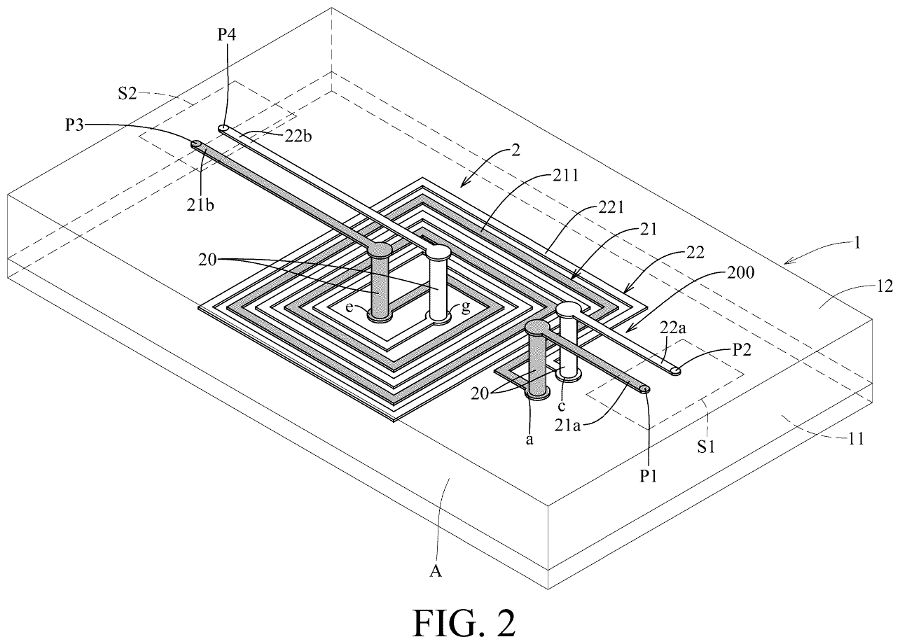

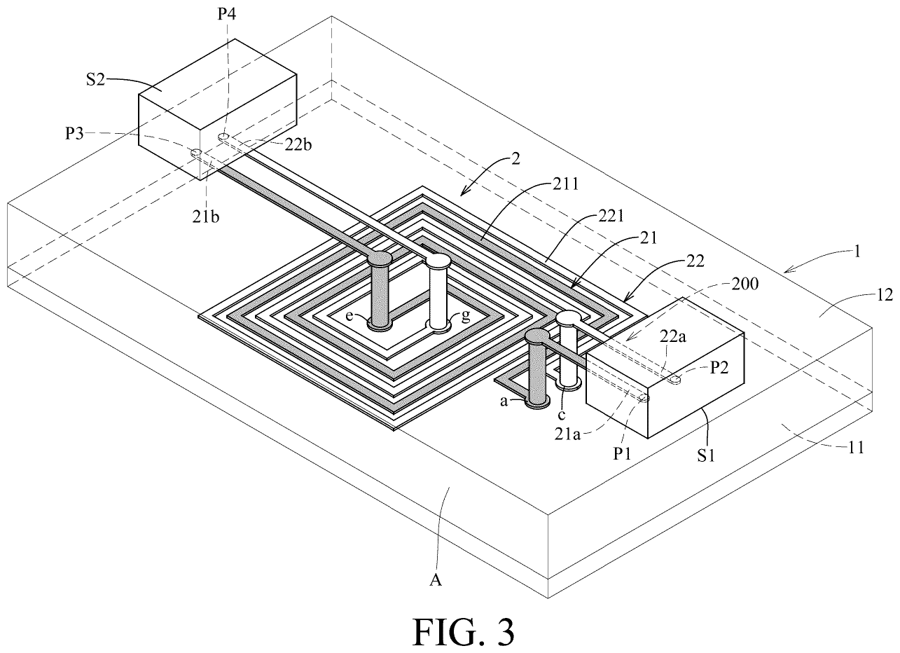

Referring to FIGS. 2 and 3, a circuit board module capable of suppressing common mode noise according to a first embodiment of the present disclosure includes a circuit board 1, a first circuit (S1) and a second circuit (S2) that are disposed on the circuit board 1. According to the present disclosure, the circuit board 1 includes an insulating substrate (A), and at least two metal layers disposed in the insulating substrate (A) and spaced apart from each other. In the first embodiment, the metal layers include a first metal layer 11 and a second metal layer 12. The circuit board 1 may be exemplified as, for example, a printed circuit board (PCB), a Chip-on-Wafer-on-Substrate (CoWoS) circuit board, an Integrated Fan-Out (InFO) circuit board, a Low-Temperature Co-fired Ceramic (LTCC) circuit board or other circuit boards of similar type, but the disclosure is not limited in this respect. In this embodiment, the second metal layer 12 has first connecting nodes (P1, P2), and second connecting nodes (P3, P4). In one embodiment, the first connecting nodes (P1, P2) and the second connecting nodes (P3, P4) may be formed on another metal layer (e.g., the first metal layer 11). In one embodiment, the first connecting nodes (P1, P2) may be formed on a different metal layer from the second connecting nodes (P3, P4). However, this disclosure is not limited in this respect.

The circuit board 1 includes a transmission interface 200 in which the first metal layer 11 and the second metal layer 12 are formed to include conducting lines 21, 22. Each of the conducting lines 21, 22 has a first end (21a, 22a) connected to a respective one of the first connecting nodes (P1, P2), and a second end (21b, 22b) connected to a respective one of the second connecting nodes (P3, P4). In other embodiments, a number of the conducting lines 21, 22 may be more than two, but the disclosure is not limited in this respect. In this embodiment, the first circuit (S1) is electrically connected to the first connecting nodes (P1, P2), and the second circuit (S2) is electrically connected to the second connecting nodes (P3, P4). The conducting lines 21, 22 cooperatively form a common mode choke structure 2 in which the conducting lines 21, 22 extend parallel and side by side in a spiral pattern, so that each of the conducting lines 21, 22 has a spiral winding segment 211, 221 in the spiral pattern. Specifically, the conducting line 21 has the spiral winding segment 211, and the conducting line 22 has the spiral winding segment 221. In this embodiment, the common mode choke structure 2 is formed on the first metal layer 11. In some embodiments, the conducting lines 21, 22 may cooperatively form the common mode choke structure 2 on another one or more of the metal layers of the circuit board 1. In the spiral pattern, a mutual inductance coupling coefficient between the spiral winding segments 211, 221 that are adjacent to each other is greater than 0.3. Specifically, the mutual inductance coupling coefficient between the spiral winding segments 211, 221 is a measure of a degree of magnetic coupling between the spiral winding segments 211, 221. In some embodiments, the mutual inductance coupling coefficient may be defined as a ratio of an actual voltage ratio of the spiral winding segments 211, 221 in an open circuit to a voltage ratio that would be obtained if all magnetic flux were coupled from one spiral winding segment to the other. Mathematically, the mutual inductance coupling coefficient is related to a mutual inductance and inductances of the spiral winding segments 211, 221, expressed as: M=\sqrt{L1·L2}, where “M” represents the mutual inductance between the spiral winding segments 211, 221, “L1” and “L2” represent the inductances respectively of the spiral winding segments 211, 221, and “k” represents the mutual inductance coupling coefficient, which ranges from 0 (no coupling) to 1 (perfect coupling).

The circuit board 1 further includes a plurality of conductor units 20 for providing electrical connections between different metal layers. The spiral winding segment 211 has a first terminal (a) located at an outermost winding of the spiral winding segment 211, and the spiral winding segment 221 has a second terminal (c) located at an outermost winding of the spiral winding segment 221. The first terminal (a) of the spiral winding segment 211 and the second terminal (c) of the spiral winding segment 221 are respectively connected to the first ends (21a, 22a) respectively of the conducting lines 21, 22 through the conductor units 20. The spiral winding segment 211 further has a third terminal (e) located at an innermost winding of the spiral winding segment 211, and the spiral winding segment 221 further has a fourth terminal (g) located at an innermost winding of the spiral winding segment 221. The third terminal (e) of the spiral winding segment 211 and the fourth terminal (g) of the spiral winding segment 221 are respectively connected to the second ends (21b, 22b) respectively of the conducting lines 21, 22 through the conductor units 20.

More specifically, in some examples, by designating the line widths of the spiral winding segments 211, 221, the spacing between the spiral winding segments 211, 221, the number of windings of the spiral winding segments 211, 221, the total area occupied by the spiral winding segments 211, 221, and the total length of the spiral winding segments 211, 221 to name but a few, the mutual inductance coupling coefficient between the spiral winding segments 211, 221 may be made greater than 0.3. Specifically, the mutual inductance between the spiral winding segments 211, 221 is formed by interactions between inductances generated respectively by the spiral winding segments 211, 221. By way of these arrangements, a positive inductive coupling is generated between the spiral winding segments 211, 221.

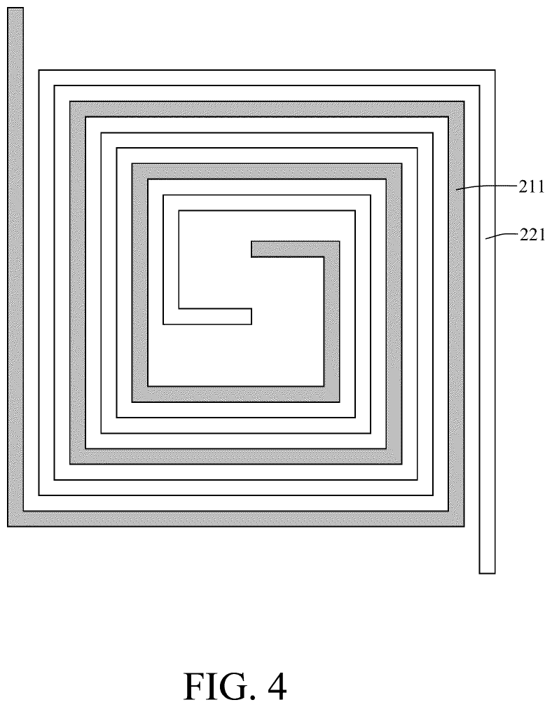

It should be noted that, in this embodiment, the spiral pattern that includes the spiral winding segments 211, 221 is in a shape of a rectangle as shown in FIG. 2. However, in other embodiments, the spiral pattern may be in a circular shape or other shapes. Furthermore, as shown in FIG. 4, the spiral winding segments 211, 221 are point-symmetrically wound around each other to form a point-symmetric pattern, that is, when the spiral pattern is rotated 180 degrees, the spiral pattern after the 180 degrees rotation overlaps the spiral pattern before the 180 degrees rotation.

Additionally, the spiral winding segments 211, 221 need not be formed on the same metal layer. In some embodiments, the spiral winding segments 211, 221 may be formed respectively on different metal layers of the circuit board 1 that are vertically stacked. For example, the spiral winding segment 211 may be formed on the first metal layer 11 of the circuit board 1, and the spiral winding segment 221 may be formed on the second metal layer 12 of the circuit board 1. That is to say, the positions of the spiral winding segments 211, 221 with respect to the metal layers of the circuit board 1 are not limited, as long as projections respectively of the spiral winding segments 211, 221 onto the same plane that is parallel to the metal layers 11, 12 produce the spiral pattern (i.e., the projections extend side by side in the spiral pattern on the same plane).

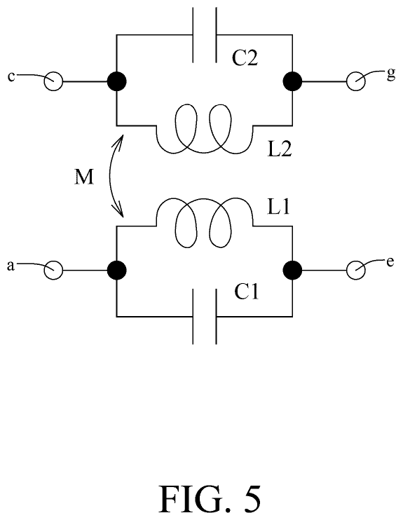

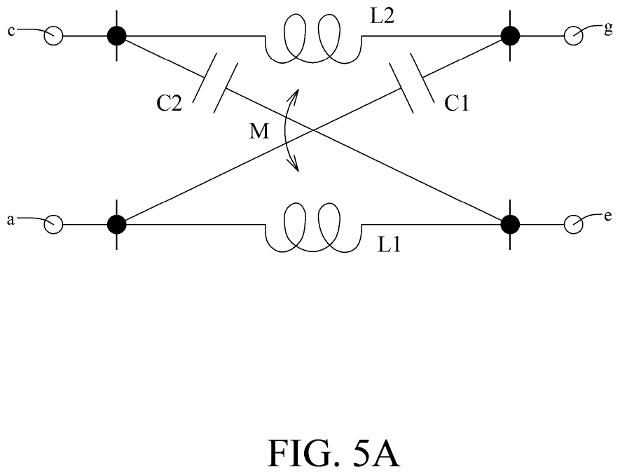

Further referring to FIG. 5, “L1” represents the inductance of the spiral winding segment 211, “L2” represents the inductance of the spiral winding segment 221, “M” represents the mutual inductance between the spiral winding segments 211, 221, “C1” represents a parasitic capacitance of the spiral winding segment 211, and “C2” represents a parasitic capacitance of the spiral winding segment 221. Interactions among these elements produce two parallel LC resonant cavities.

When the first circuit (S1) transmits a differential mode signal to the second circuit (S2) through the spiral winding segments 211, 221 of the conducting lines 21, 22, a common mode noise signal also enters the spiral winding segments 211, 221 of the conducting lines 21, 22 from the first circuit (S1) at the same time. When currents associated respectively to the differential mode signal and the common mode noise signal flow through the spiral winding segments 211, 221, the two parallel LC resonant cavities generate open-circuit resonances, which suppress the common mode noise signal, thereby inhibiting transmission of the common mode noise signal. Specifically, when the current that is associated with the common mode noise signal flows through the spiral winding segments 211, 221, magnetic flux lines that are generated respectively by the spiral winding segments 211, 221 align in the same direction, causing the magnetic fluxes to superimpose. As a result, a significant inductance is generated in the spiral winding segments 211, 221, thereby suppressing the current that is associated with the common mode noise signal and inhibiting the transmission of the common mode noise signal; when the current that is associated with the differential mode signal flows through the spiral winding segments 211, 221, the magnetic flux lines that are generated respectively by the spiral winding segments 211, 221 oppose each other, causing the magnetic fluxes to cancel out. As a result, an effective inductance of the spiral winding segments 211, 221 is very small, allowing the differential mode signal to pass through.

Therefore, the circuit board module of this disclosure is able to achieve common mode noise suppression without using ferromagnetic materials (i.e., a magnetic core normally used in a conventional common mode choke). Without using ferromagnetic materials, a common mode noise suppression capability of the circuit board module of this disclosure is unaffected by frequency-dependent characteristics of the ferromagnetic materials. Specifically, when the circuit board module of this disclosure performs a transmission of a high-frequency signal, since no ferromagnetic materials are used, the mutual inductance generated between the spiral winding segments 211, 221 of the conducting lines 21, 22 is not impacted by characteristics of the ferromagnetic materials, which otherwise may cause the mutual inductance to decrease, and may cause the common mode noise suppression capability to also decrease. Therefore, by virtue of this arrangement, the circuit board module of this disclosure may not cause an increase in the insertion loss of the differential mode signal nor affect the common mode noise suppression capability during a transmission of the differential mode signal.

In some embodiments, one of the first circuit (S1) and the second circuit (S2) is a connector of the transmission interface 200, and the other one of the first circuit (S1) and the second circuit (S2) is an integrated circuit element. The connector of the transmission interface 200 is exemplified as, for example, but not limited to, an external connector or a gold finger (also known as an edge connector) integrally formed on the circuit board 1. In some embodiments, at least one of the first circuit (S1) or the second circuit (S2) is an embedded element formed by one or more of the metal layers. In some other embodiments, at least one of the first circuit (S1) or the second circuit (S2) includes one or more circuit components. For example, the first circuit (S1) may include electrostatic protection components that are electrically connected respectively to the first connecting nodes (P1, P2).

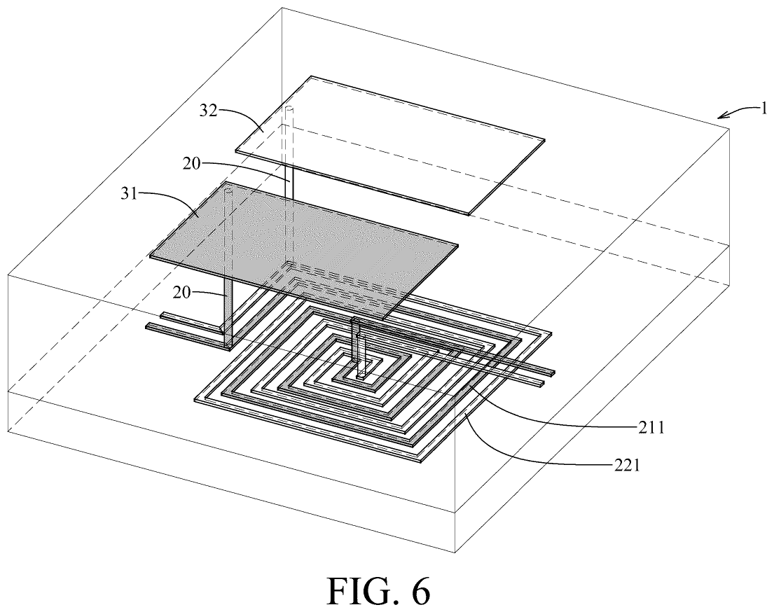

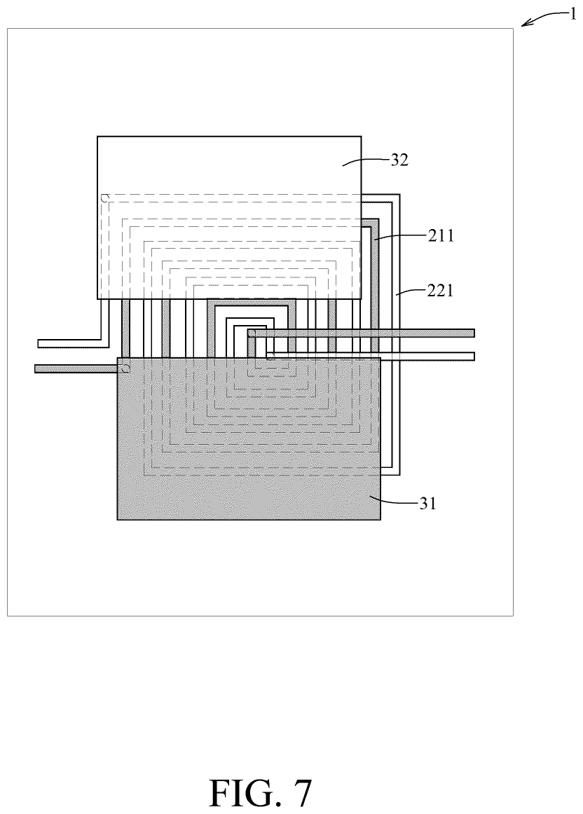

Referring to FIGS. 6 and 7, the common mode choke structure 2 of the circuit board 1 according to a second embodiment of the present disclosure is presented. In the second embodiment that is similar to the first embodiment, the metal layers further include first conducting elements 31, 32. The first conducting elements 31, 32 are electrically connected respectively to the spiral winding segments 211, 221, and are capacitively coupled to the spiral winding segments 211, 221.

Specifically, the first conducting elements 31, 32 are formed on one of the metal layers that is different from the metal layer on which the spiral winding segments 211, 221 are formed. In the illustrative embodiment, the first conducting element 31 is a metal pad connected to the spiral winding segment 211 (e.g., through a respective one of the conductor units 20), and partially overlaps the spiral winding segments 211, 221, and thus is capacitively coupled to the spiral winding segments 211, 221. The first conducting element 32 is a metal pad connected to the spiral winding segment 221, and partially overlaps the spiral winding segments 211, 221, and thus is capacitively coupled to the spiral winding segments 211, 221. By virtue of the abovementioned configuration, parasitic capacitances (C1, C2) of the conducting lines 21, 22 and the first conducting elements 31, 32 can be adjusted by adjusting overlapping areas between the first conducting elements 31, 32 and the spiral winding segments 211, 221. Based on different designs of the first conducting elements 31, 32, the common mode choke structure 2 of this second embodiment can be designed to produce an equivalent circuit that is similar to the equivalent circuit in FIG. 5 or FIG. 5A.

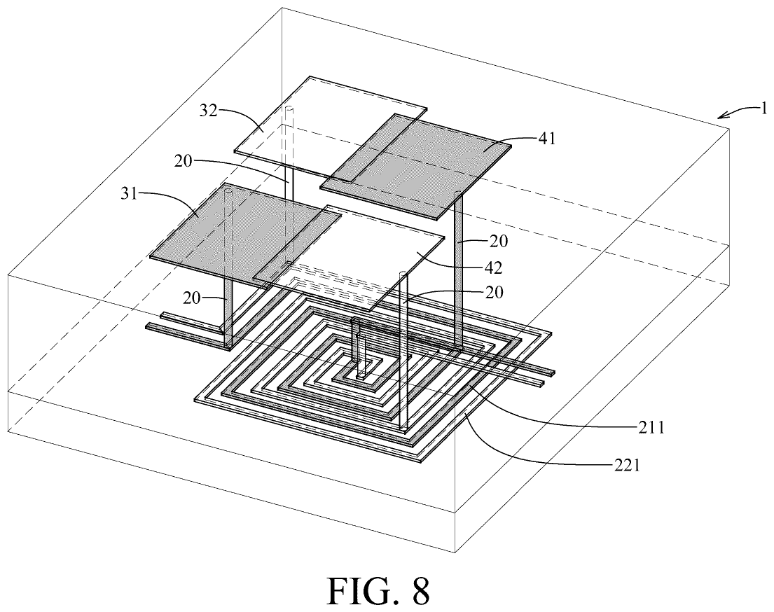

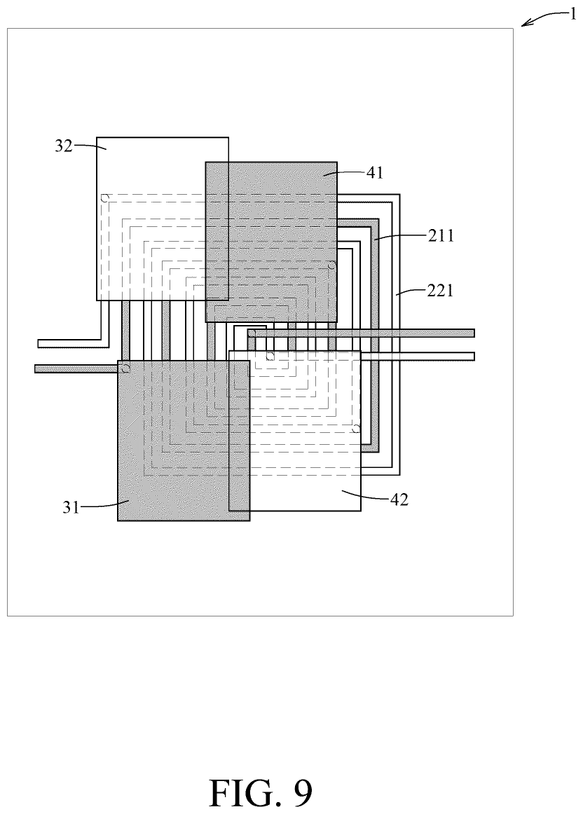

Referring to FIGS. 8 and 9, the common mode choke structure 2 of the circuit board 1 according to a third embodiment of the present disclosure is presented. The common mode choke structure 2 of the third embodiment is similar to the common mode choke structure 2 of the second embodiment, but differs in that, in addition to the first conducting elements 31, 32, the metal layers of the third embodiment further include second conducting elements 41, 42. The second conducting elements 41, 42 are spaced apart from the first conducting elements 31, 32, are electrically connected respectively to the spiral winding segments 211, 221, and thus are capacitively coupled to the first conducting elements 31, 32.

Specifically, the second conducting elements 41, 42 are formed on one of the metal layers that is different from the metal layer on which the first conducting elements 31, 32 are formed. In the illustrative embodiment, the second conducting element 41 is a metal pad electrically connected to the spiral winding segment 211 (e.g., through a respective one of the conductor units 20), partially overlaps the first conducting element 32, and thus is capacitively coupled with the first conducting element 32. The second conducting element 42 is a metal pad electrically connected to the spiral winding segment 221, partially overlaps the first conducting element 31, and thus is capacitively coupled with the first conducting element 31. In the third embodiment, a point of connection between the spiral winding segment 211 and the first conducting element 31, and a point of connection between the spiral winding segment 211 and the second conducting element 41 are set to be as far away from each other as possible. A point of connection between the spiral winding segment 221 and the first conducting element 32, and a point of connection between the spiral winding segment 221 and the second conducting element 42 are also set to be as far away from each other as possible. By virtue of the abovementioned configuration, parasitic capacitances (C1, C2) of the conducting lines 21, 22 can be adjusted by adjusting overlapping areas between the second conducting element 41 and the first conducting element 32, and between the second conducting element 42 and the first conducting element 31. By making the aforementioned adjustments, the common mode choke structure 2 of the third embodiment is able to produce an equivalent circuit that is similar to the equivalent circuit in FIG. 5A.

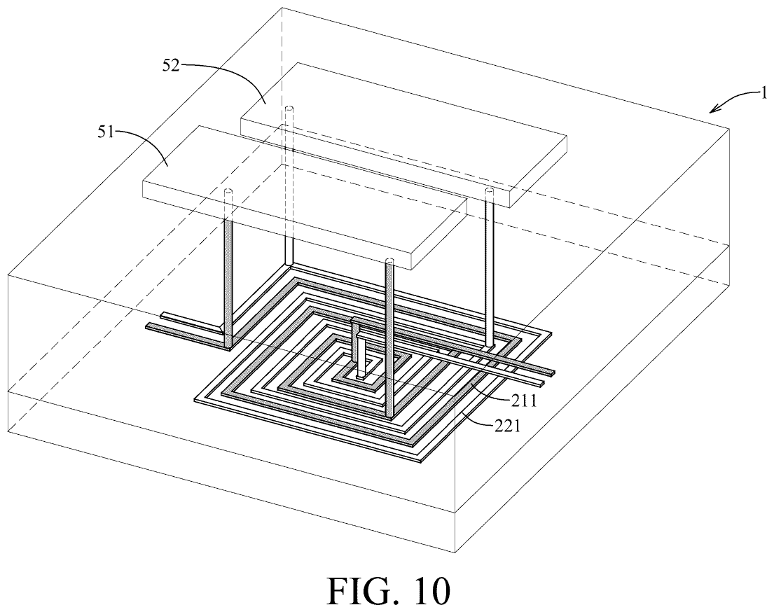

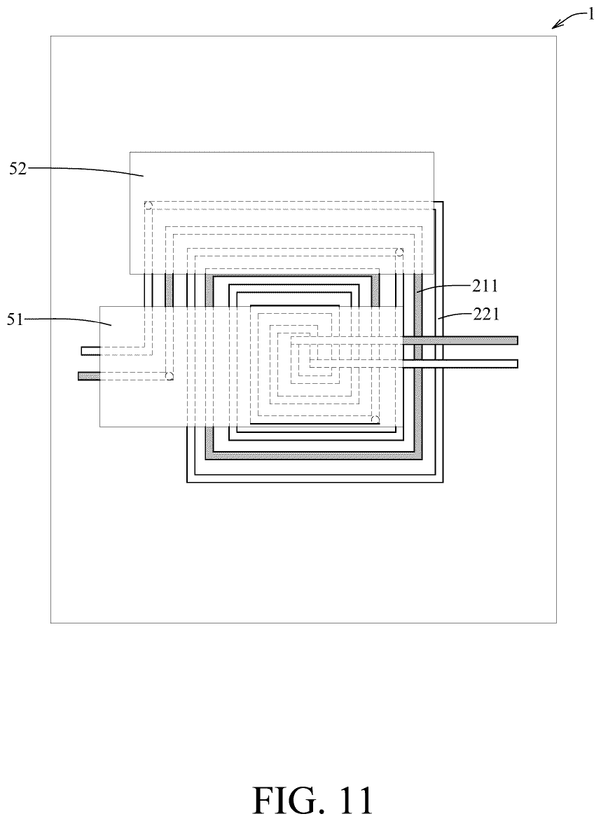

Referring to FIGS. 10 and 11, the common mode choke structure 2 of the circuit board 1 according to a fourth embodiment is presented. In the fourth embodiment that is similar to the first embodiment, each of the spiral winding segments 211, 221 is connected to a respective first capacitive element 51, 52 at two points. For example, the first capacitive element 51 is connected to two points on the spiral winding segment 211, and the first capacitive element 52 is connected to two points on the spiral winding segment 221. Each of the first capacitive elements 51, 52 may be exemplified by, for example, but not limited to, a capacitor, a diode, a transistor, or other independent element that has capacitive characteristics. By virtue of the abovementioned configuration, parasitic capacitances (C1, C2) of the conducting lines 21, 22 can be adjusted using the first capacitive elements 51, 52 in order to produce an equivalent circuit that is similar to the equivalent circuit in FIG. 5.

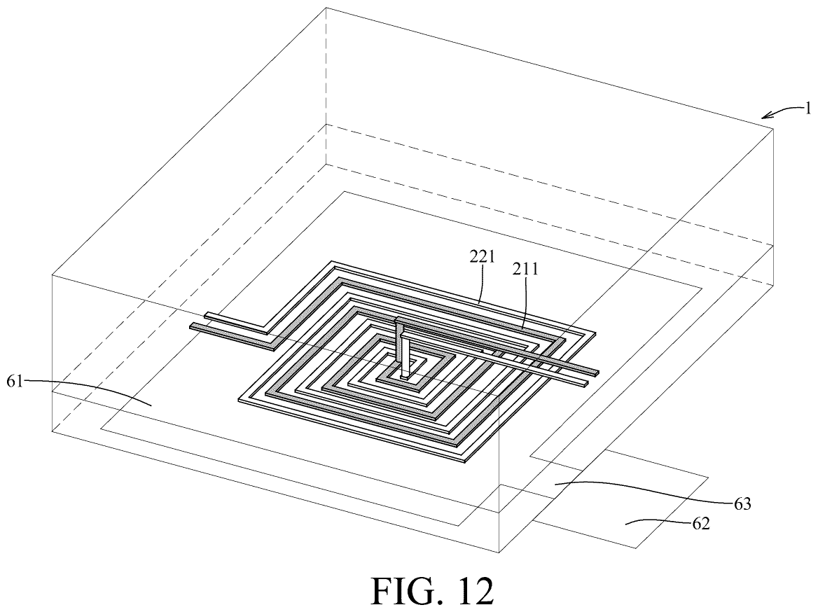

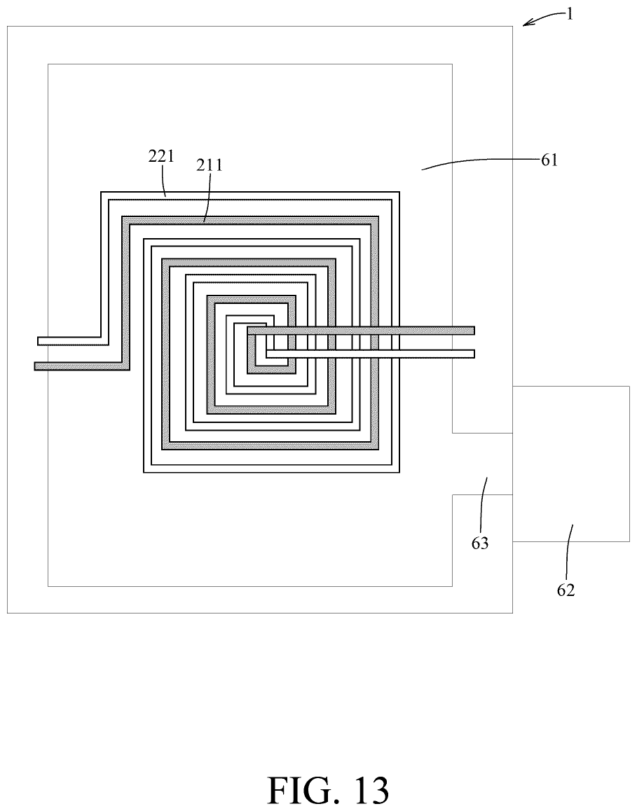

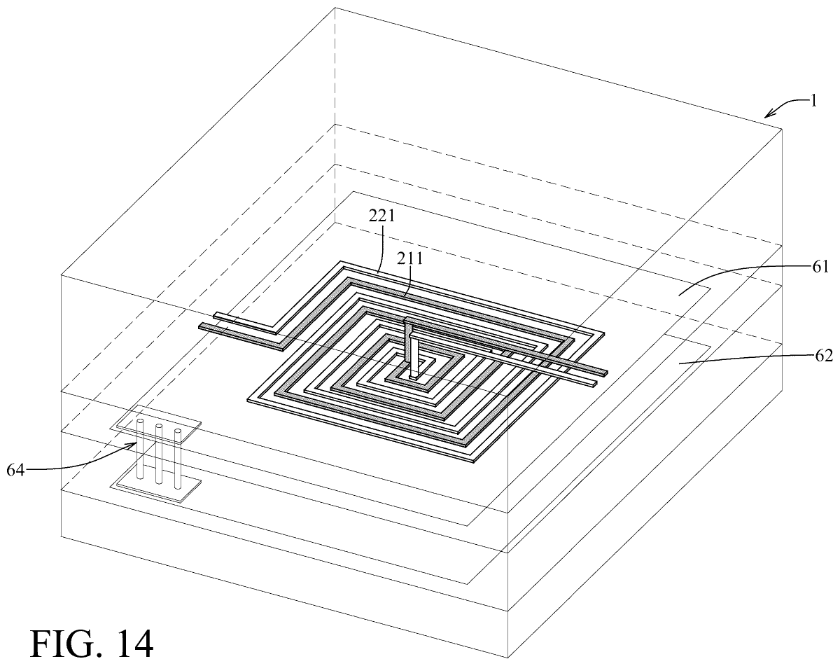

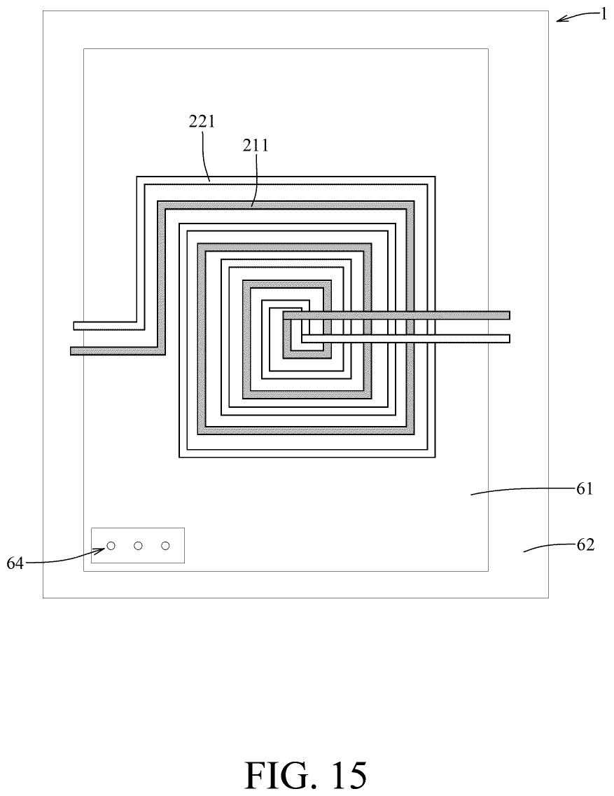

Referring to FIGS. 12 and 13, the common mode choke structure 2 of the circuit board 1 according to a fifth embodiment of the present disclosure is presented. In the fifth embodiment that is similar to the first embodiment, the metal layers further include a third conducting element 61, a first system ground 62 (only a portion of the first system ground 62 is shown in FIG. 12) and a connecting trace 63. The third conducting element 61 is capacitively coupled to the spiral winding segments 211, 221, and is connected to the first system ground 62. Specifically, the third conducting element 61 is formed on one of the metal layers that is different from the metal layer on which the spiral winding segments 211, 221 are formed. In some embodiments, the third conducting element 61 is on the same one of the metal layers as the first system ground 62 (as shown in FIG. 12), the third conducting element 61 may connect with the first system ground 62 through the connection trace 63. In some embodiments, the third conducting element 61 is on one of the metal layers that is different from the metal layer on which the first system ground 62 is formed (as shown in a variation of the common mode choke structure 2 of the fifth embodiment in FIG. 14), the third conducting element 61 may be connected to the first system ground 62 through a connecting unit 64 (as shown in FIGS. 14 and 15) that extends vertically to connect different metal layers. The connecting unit 64 may be exemplified as, for example, but not limited to, a set of metal pillars, a set of plated through holes, a spiral structure, an electronic component, or any combination thereof.

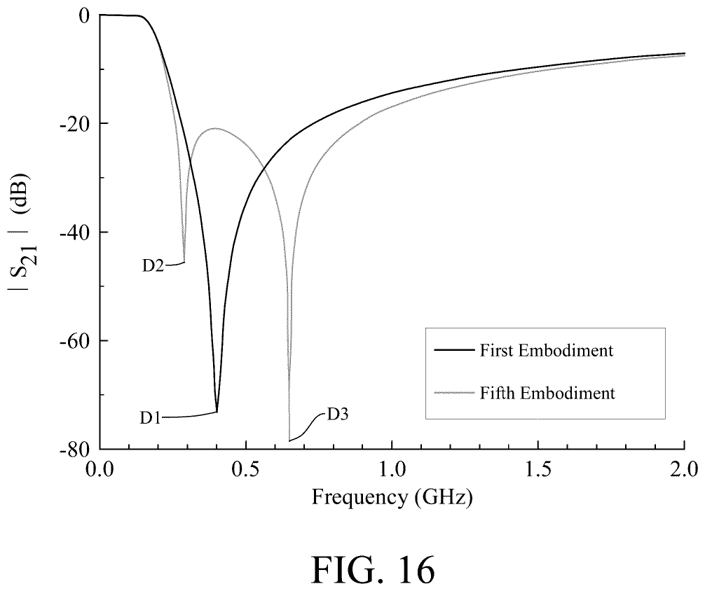

Referring to FIG. 16, the first embodiment with the equivalent circuit in FIG. 5 determines a common mode transmission zero (D1) through interactions of the inductance and the parasitic capacitance of the conducting lines 21, 22 of the first embodiment. In the fifth embodiment, aside from the interactions of the inductance and the parasitic capacitance of the conducting lines 21, 22 of the fifth embodiment determining a common mode transmission zero (D2), a capacitive coupling between the spiral winding segments 211, 221 and the third conducting element 61 produces another common mode transmission zero (D3). As shown in the S21 plot for the first embodiment and the fifth embodiment in FIG. 16, the first embodiment demonstrates a single transmission zero (D1), located at 0.4 GHz, whereas the fifth embodiment demonstrates two transmission zeros (D2, D3), located at 0.3 GHz and 0.65 GHz, respectively. By looking at the S21 plot of the common mode noise signal at −20 dB, the first embodiment is able to suppress the common mode noise signal within a frequency range of approximately 0.3 GHz to 0.7 GHz (i.e., over a bandwidth of 0.4 GHz), whereas the fifth embodiment is able to suppress the common mode noise signal within a frequency range of approximately 0.3 GHz to 0.9 GHz (i.e., over a bandwidth of 0.6 GHz). Therefore, the fifth embodiment is able to suppress the common mode noise signal at a wider frequency bandwidth than the first embodiment.

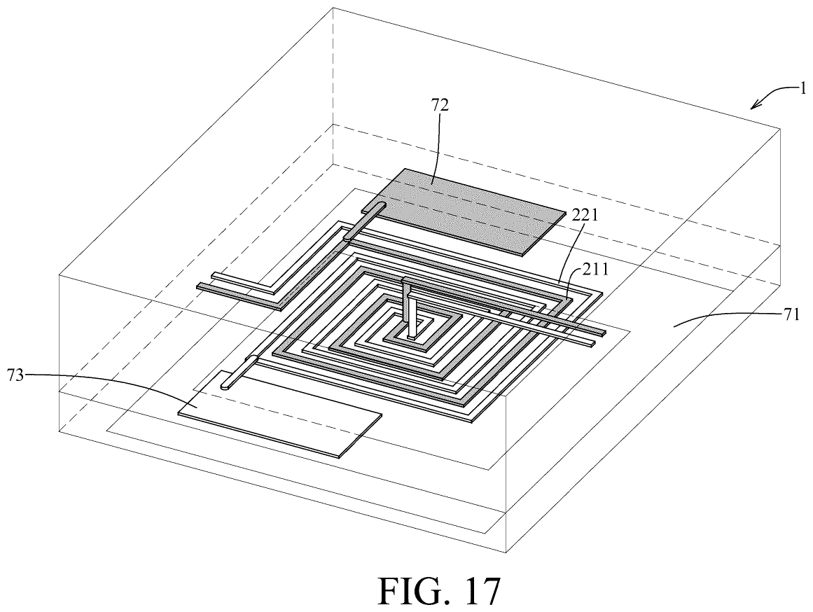

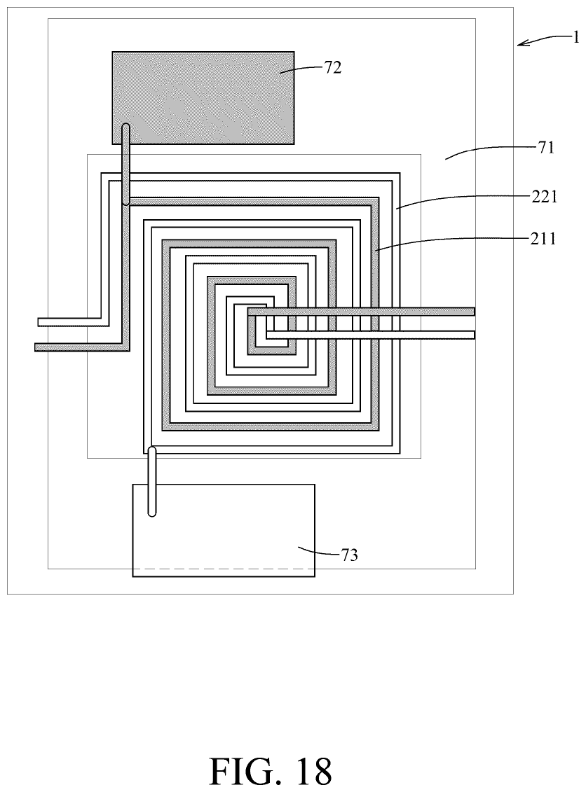

Referring to FIGS. 17 and 18, the common mode choke structure 2 of the circuit board 1 according to a sixth embodiment of the present disclosure is presented. In the sixth embodiment that is similar to the first embodiment, the metal layers further include a defected conducting element 71. A projection of the defected conducting element 71 onto one of the metal layers where the spiral winding segments 211, 221 are located is spaced apart from and surrounding the spiral winding segments 211, 221. The metal layers further include fourth conducting elements 72, 73. The fourth conducting elements 72, 73 are connected respectively to the spiral winding segments 211, 221, overlap at least a portion of the defected conducting element 71, and thus are capacitively coupled with the defected conducting element 71.

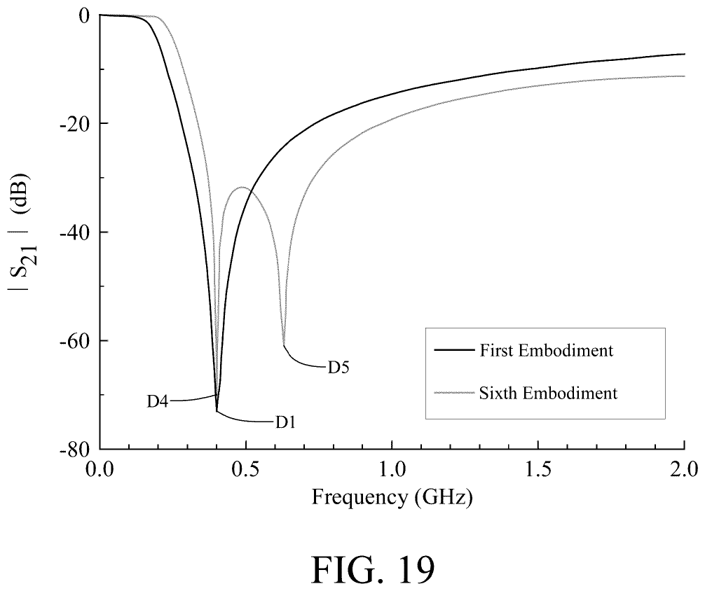

Specifically, the defected conducting element 71 is formed on one of the metal layers that is different from the metal layer(s) on which the fourth conducting elements 72, 73 are located. The defected conducting elements 71 may be formed on the same one of the metal layers on which the spiral winding segments 211, 221 are located, or may be formed on one of the metal layers that is different from the metal layer on which the spiral winding segments 211, 221 are located. The fourth conducting element 72 is connected to the spiral winding segment 211, at least partially overlaps the defected conducting element 71, and thus is capacitively coupled with the defected conducting element 71. The fourth conducting element 73 is connected to the spiral winding segment 221, at least partially overlaps the defected conducting element 71, and thus is capacitively coupled with the defected conducting element 71. Referring to the S21 plot in FIG. 19, the plot of the first embodiment exhibits the common mode transmission zero (D1). The plot of the sixth embodiment exhibits a common mode transmission zero (D4) that is determined by the interactions of the inductance and the parasitic capacitance between the conducting lines 21, 22 of the sixth embodiment, and another common mode transmission zero (D5) that is determined by a capacitive coupling between the fourth conducting elements 72, 73 and the defected conducting element 71. As shown in FIG. 19, the sixth embodiment demonstrates two transmission zeros (D4, D5), located at 0.4GHz and 0.6 GHz, respectively. The presence of the common mode transmission zeros (D4, D5) allows for suppression of the common mode noise signal across a wider frequency spectrum of approximately 0.35 GHz to 1.0 GHz (i.e., over a bandwidth of 0.65 GHz) at −20 dB for the sixth embodiment as compared to approximately 0.3 GHz to 0.7 GHz (i.e., over a bandwidth of 0.4 GHz) at −20 dB for the first embodiment.

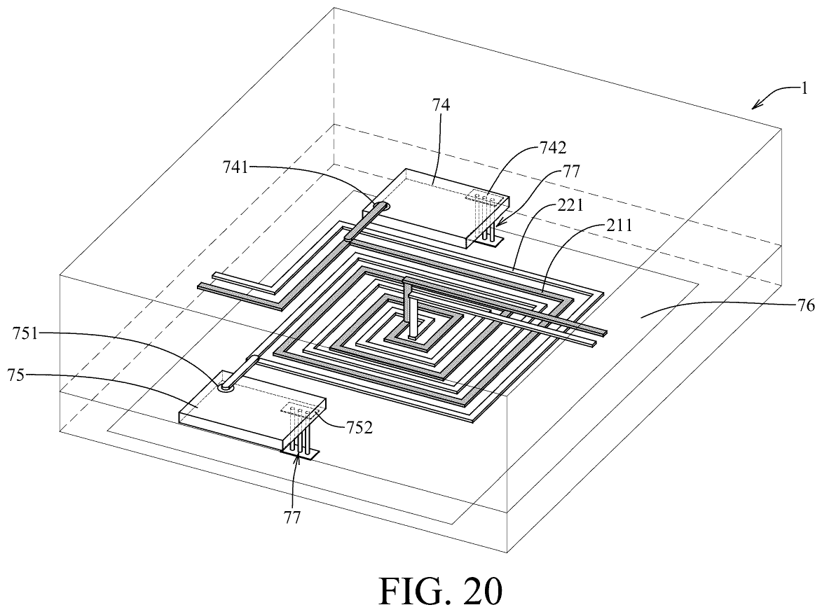

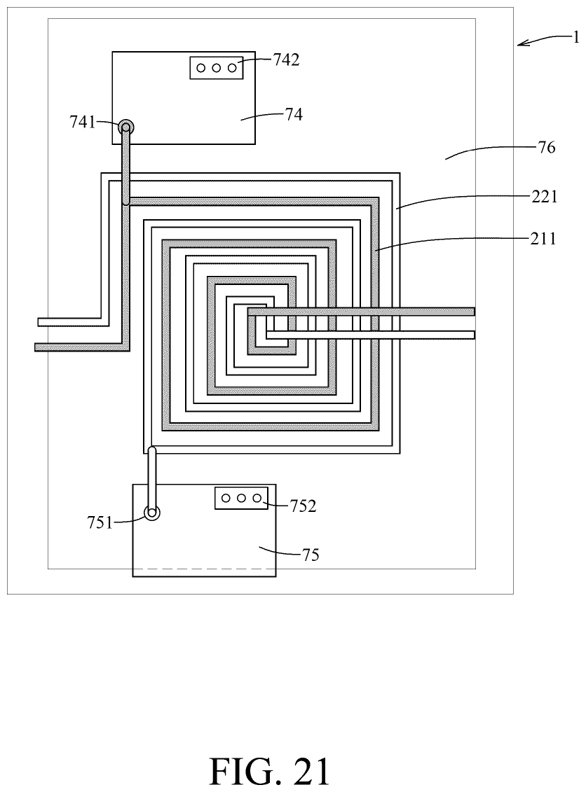

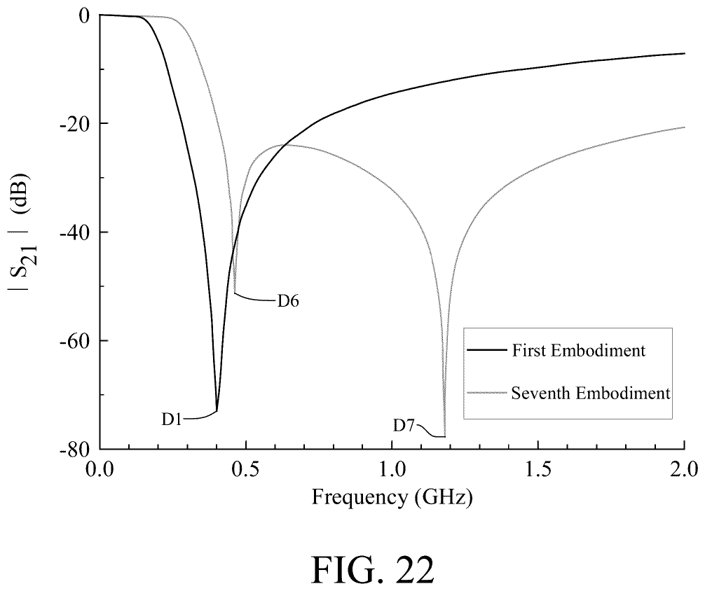

Referring to FIGS. 20 and 21, the common mode choke structure 2 of the circuit board 1 according to a seventh embodiment of the present disclosure is presented. The seventh embodiment is similar to the first embodiment, and further includes second capacitive elements 74, 75. Each of the second capacitive elements 74, 75 has a terminal 741, 751 connected to a respective one of the spiral winding segments 211, 221, and another terminal 742, 752 connected to a second system ground 76. Each of the second capacitive elements 74, 75 may be exemplified by, for example, but not limited to, a capacitor, a diode, a transistor or other independent component with capacitive characteristics. The second capacitive elements 74, 75 may be formed on one of the metal layers that is different from the metal layer on which the spiral winding segments 211, 221 are formed. The second capacitive elements 74, 75, are disposed at one of the metal layers that is different from the metal layer on which the second system ground 76 is formed, and may be connected to the second system ground 76 through a connecting unit 77 that extends vertically to connect different metal layers. The second connecting unit 77 may be exemplified as, for example, but not limited to, a set of metal pillars, a set of plated through holes, a spiral structure, an electronic component, or any combination thereof. In some embodiments, the second capacitive elements 74, 75 may be disposed at the same one of the metal layers as the second system ground 76, and the disclosure is not limited in this respect. Referring to FIG. 22, the S21 plot of the seventh embodiment exhibits a common mode transmission zero (D6) that is determined by the interactions of the inductance and the parasitic capacitance between the conducting lines 21, 22 of the seventh embodiment, and a common mode transmission zero (D7) that is determined by the presence of the second capacitive elements 74, 75. As shown in FIG. 22, the seventh embodiment demonstrates two transmission zeros (D6, D7), located at 0.45 GHz and 1.2 GHz, respectively. The presence of the common mode suppression depth points (D6, D7) allows for suppression of the common mode noise signal across a wider frequency spectrum of approximately 0.45 GHz to more than 2.0 GHz (i.e., over a bandwidth of more than 1.55 GHz) at −20 dB for the seventh embodiment as compared to approximately 0.3 GHz to 0.7 GHz (i.e., over a bandwidth of 0.4 GHz) at −20 dB for the first embodiment.

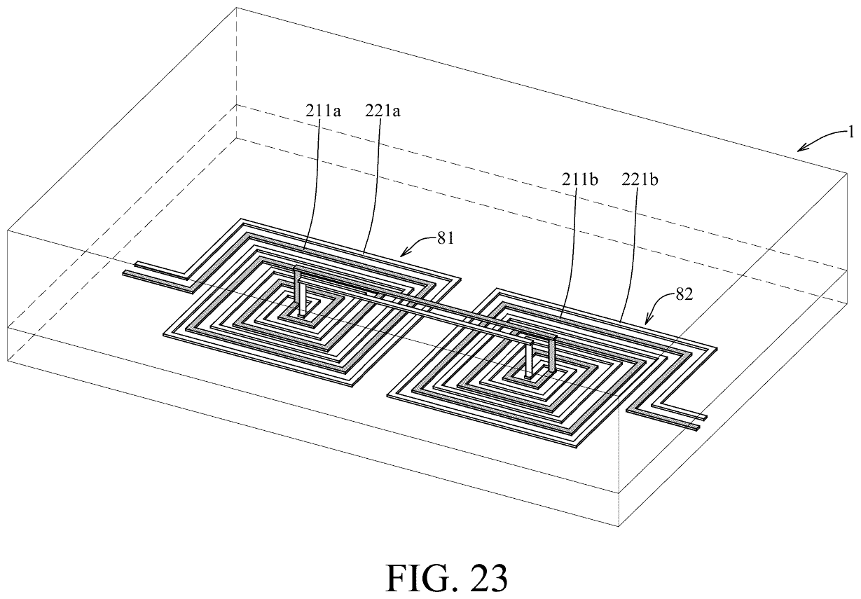

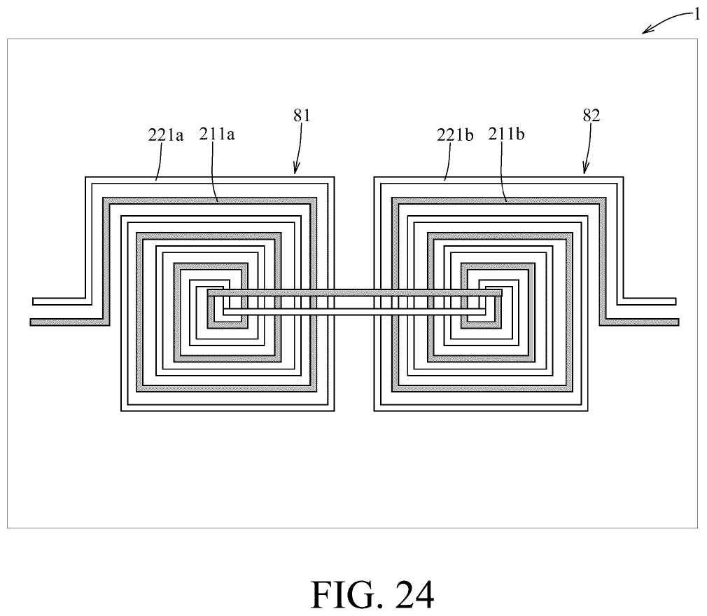

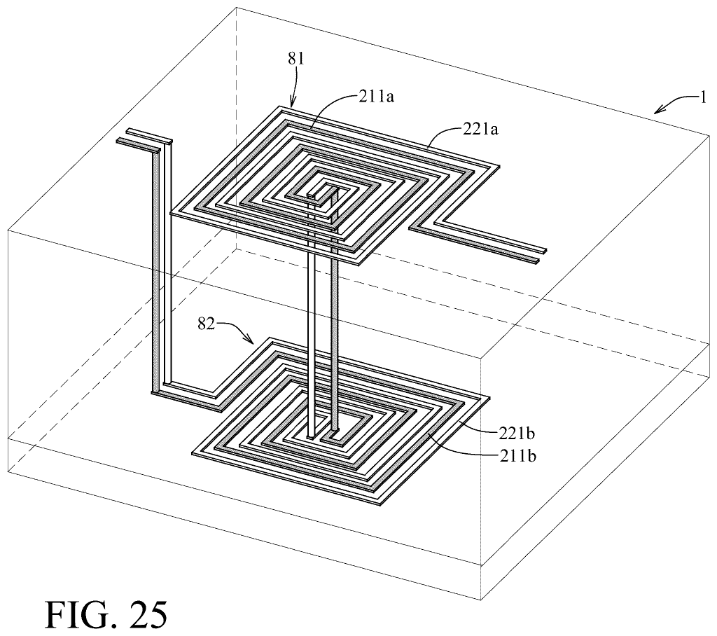

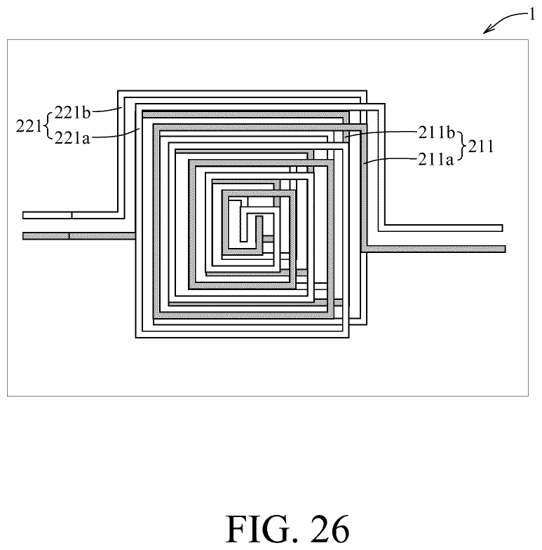

Referring to FIGS. 23 and 24, a variation of the spiral pattern according to the first embodiment of the present disclosure is presented. In this variation, the spiral pattern includes spiral sub-patterns 81, 82 that are connected in series and that are disposed side by side to each other. The spiral winding segment 211 includes spiral windings (211a, 211b) respectively in the spiral sub-patterns 81, 82, and the spiral winding segment 221 includes the spiral windings (221a, 221b) respectively in the spiral sub-patterns 81, 82. In some embodiments, the spiral sub-patterns 81, 82 may be formed on the same metal layer, as shown in FIG. 23. In some embodiments, the spiral sub-patterns 81, 82 may be formed on different metal layers, as shown in FIGS. 25 and 26, where the spiral sub-patterns 81, 82 overlap at least partially in a thickness direction of the circuit board 1. Besides that, the spiral sub-patterns 81, 82 may have either the same surface area or different surface areas. It should be noted that the configurations employed in embodiments illustrated in FIGS. 6 to 15, 17, 18, 20, and 21 may also be employed on at least one of the spiral sub-patterns 81, 82.

It should be noted again that the number of the conducting lines may be more than two. For example, the metal layers may include three conducting lines that cooperatively form the common mode choke structure 2 capable of suppressing the common mode noise signal transmitted on two of the conducting lines at a time. The three conducting lines extend side by side in the spiral pattern, so that each of the three conducting lines has the spiral winding segment in the spiral pattern, and the mutual inductance coupling coefficient between the spiral winding segments of any two adjacent ones of the three conducting lines is greater than 0.3.

To sum up, the circuit board 1 includes the conducting lines 21, 22 that cooperatively form the common mode choke structure 2 by extending side by side in the spiral pattern. This arrangement enables the common mode choke structure 2 to be integrated into the transmission interface 200 of the circuit board 1, and enables the circuit board 1 to have the common mode noise suppression capability without requiring surface mount technology (SMT) components. Additionally, since embedded components are connected within inner layers of the circuit board 1, surface-layer routing space of the circuit board 1 is freed up, and since no ferromagnetic materials are used, signal transmission and noise suppression capabilities of the conducting lines 21, 22 are not affected by properties of the ferromagnetic materials. In some embodiments, by virtue of the common mode choke structure 2 including capacitive elements that enable control of the capacitances between the capacitive elements and the conducting lines 21, 22, the frequency of the common mode transmission zero(s) may be lowered according to actual application requirements without increasing the inductances of the conducting lines 21, 22, and increase in line losses of the conducting lines 21, 22 may be prevented.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A circuit board module capable of suppressing common mode noise, comprising:
a circuit board including
an insulating substrate; and
a plurality of metal layers disposed in said insulating substrate and spaced apart from each other, said plurality of metal layers including a first metal layer that has a plurality of first connecting nodes, and a second metal layer that has a plurality of second connecting nodes;
a first circuit disposed on said circuit board and electrically connected to said plurality of first connecting nodes; and
a second circuit disposed on said circuit board and electrically connected to said plurality of second connecting nodes,
wherein said plurality of metal layers are formed to include a plurality of conducting lines, each having an end connected to a respective one of said plurality of first connecting nodes, and another end connected to a respective one of said plurality of second connecting nodes,
wherein said plurality of conducting lines cooperatively form a common mode choke structure in which said plurality of conducting lines extend in such a way that each of said plurality of conducting lines has a spiral winding segment, and that projections respectively of said spiral winding segments of said plurality of conducting lines onto a same plane that is parallel to said plurality of metal layers extend side by side in a spiral pattern; and
wherein, in the spiral pattern, a mutual inductance coupling coefficient between said spiral winding segments of two adjacent ones of said plurality of conducting lines is greater than 0.3.

2. The circuit board module as claimed in claim 1, wherein said plurality of metal layers further include a plurality of first conducting elements, each being electrically connected to a respective one of said spiral winding segments of said plurality of conducting lines, and being capacitively coupled to said spiral winding segments of said plurality of conducting lines.

3. The circuit board module as claimed in claim 2, wherein said plurality of metal layers further include a plurality of second conducting elements that are spaced apart from said plurality of first conducting elements, that are electrically connected respectively to said spiral winding segments of said plurality of conducting lines, and that are capacitively coupled to said plurality of first conducting elements.

4. The circuit board module as claimed in claim 1, wherein each of said spiral winding segments of said plurality of conducting lines is connected to a respective capacitive element at two points.

5. The circuit board module as claimed in claim 1, wherein said plurality of metal layers further include a conducting element that is capacitively coupled to said spiral winding segments of said plurality of conducting lines and that is connected to a system ground.

6. The circuit board module as claimed in claim 1, wherein said plurality of metal layers further include a defected conducting element, and a plurality of conducting elements that are connected respectively to said spiral winding segments of said plurality of conducting lines, said plurality of conducting elements overlapping a portion of said defected conducting element and being capacitively coupled with said defected conducting element.

7. The circuit board module as claimed in claim 1, wherein each of said spiral winding segments of said plurality of conducting lines is connected to a terminal of a respective capacitive element, and each capacitive element has another terminal connected to a system ground.

8. The circuit board module as claimed in claim 1, wherein one of said first circuit and said second circuit is a connector of a transmission interface, and the other one of said first circuit and said second circuit is an integrated circuit element.

9. The circuit board module as claimed in claim 1, wherein at least one of said first circuit or said second circuit is an embedded element formed by at least one of said plurality of metal layers.

10. The circuit board module as claimed in claim 1, wherein the spiral pattern includes a plurality of spiral sub-patterns that are connected in series.

11. The circuit board module as claimed in claim 10, wherein any two of said plurality of spiral sub-patterns overlap at least partially in a thickness direction of said circuit board.

12. The circuit board module as claimed in claim 1, wherein said plurality of conducting lines are disposed on different ones of said plurality of metal layers.

13. The circuit board module as claimed in claim 1, wherein said plurality of conducting lines are disposed on a same one of said plurality of metal layers.
